(19) United States
(12) Patent Application Publication
(10) Pub. No.: US 2013/0083485 A1
(43) Pub. Date: Apr. 4, 2013

(54) HEAT DISSIPATION APPARATUS FOR MEDIUM-VOLTAGE DRIVE

(71) Applicants: Ai-Xing Tong, Shanghai (CN); Hong-Jian Gan, Shanghai (CN)

(72) Inventors: Ai-Xing Tong, Shanghai (CN); Hong-Jian Gan, Shanghai (CN)

(73) Assignee: DELTA ELECTRONICS (SHANGHAI) CO., LTD., Shanghai (CN)

(21) Appl. No.: 13/314,700

(22) Filed: Dec. 8, 2011

(30) Foreign Application Priority Data
Sep. 29, 2011 (CN) 201110303758.9

(51) Int. Cl. H05K 7/20

(52) U.S. Cl. 361/700

(57) ABSTRACT

A heat dissipation apparatus is suitable for dissipating heat from heat-generating elements in a medium-voltage drive. The heat dissipation apparatus comprises: a heat-dissipating substrate, wherein the heat-generating elements are placed on at least one of a first surface and a second surface of the heat-dissipating substrate; at least one heat pipe group each of which includes a plurality of heat pipes, each heat pipe having an evaporation section and a condensation section, wherein the evaporation section is buried in an inner layer of the heat-dissipating substrate for absorbing heat from the heat-generating elements; and a plurality of fins arranged to be intersected with each heat pipe and connected to the condensation sections of the heat pipes, so as to transfer the heat released from the condensation sections to air. The contact portions between the heat pipe group and the fins are arranged in triangle staggered arrangements.

### RELATED APPLICATIONS

This application claims priority to Chinese Application Serial Number 201110303758.9, filed Sep. 29, 2011, which is herein incorporated by reference.

### BACKGROUND

1. Field of Invention

The present invention relates to a heat dissipation apparatus, and more particularly to a heat dissipation apparatus for a medium-voltage drive.

2. Description of Related Art

Nowadays, a medium-voltage drive is widely applied in a number of power and electronic circuits. The medium-voltage drive is a power control apparatus, which changes frequency by turning on or off semiconductor power devices, so as to implement the functions such as soft start, variable frequency speed control, power factor changing and over-current/over-voltage/overload protection. However, the power devices often generate massive heat when being frequently switched between on and off, and thus a heat dissipation apparatus is needed to be disposed correspondingly to effectively dissipate heat generated from the power devices, thereby ensuring the normal operation of the medium-voltage drive.

Generally speaking, the heat dissipation apparatus mainly includes a flat plate heat sink, a parallel-rib heat sink and a cross-finger heat sink. The flat plate heat sink generally is a square or rectangular Al plate or Al alloy plate for dissipating heat from a low power transistor. The parallel-rib heat sink is fabricated from an Al material with parallel ribs formed by extrusion of an Al alloy, and is used for dissipating heat from a large/medium-power switch tube. The cross-finger heat sink is formed by punching an Al sheet, and is used for dissipating heat from a large/medium-power transistor.

A power module for the medium-voltage drive includes a power inverter unit, a rectifier unit, a bypass unit and a capacitor unit. In the prior art, the power inverter unit, the rectifier unit and the bypass unit are mounted on one side of a substrate of the heat sink, and a fins set on the other side of the substrate of the heat sink. The combination of the substrate and the fins adopts an integral structure formed by extrusion, a piece insertion structure or a welding structure. Although the above-mentioned power devices are mounted on the same side of the substrate of the heat sink for convenient installation, fixing and electrical connection, yet for uniformly and effectively dissipating the heat generated by the power devices during operation to air, the power devices have to be distributed at larger intervals on the substrate of the heat sink and meanwhile the thickness of the substrate needs to be increased, so as to allow the substrate to be heated evenly for improving the heat dissipation efficiency. On the other hand, the larger interval between the power devices increases the electrical connection distance, thus resulting in the increase of leakage inductance and low efficiency, further adversely affecting the performance and service life of the power devices.

In view of the foregoing, it is a problem desired to be solved by this industry regarding how to design a novel heat sink for rapidly and effectively dissipating heat from the power devices and meanwhile implement an overall compact structure of the drive by utilizing the arrangement space on the heat-dissipating substrate.

### SUMMARY

The present invention aims to provide a heat dissipation apparatus.

To achieve the above object, a technical aspect of the present invention relates to a heat dissipation apparatus which is for dissipating heat from a plurality of heat-generating elements in a medium-voltage drive. The heat dissipation apparatus includes a heat-dissipating substrate, at least one heat pipe group and a plurality of fins. The heat-dissipating substrate has a first surface, a second surface and an inner layer between the first surface and the second surface. The heat-generating elements are placed on at least one surface of the first surface and the second surface. Each heat pipe group includes a plurality of heat pipes; each heat pipe has an evaporation section and a condensation section; and the evaporation section is buried in the inner layer of the heat-dissipating substrate for absorbing the heat from the heat-generating elements. The heat sinks are arranged to be intersected with each heat pipe, and the fins are fixed and connected to the condensation section of the heat pipe, so as to transfer the heat released by the condensation section to air. The contact portions between at least one heat pipe group and the fins are in triangle staggered arrangements. The fins are intersected with each heat pipe with an intersection angle of 90°.

In a preferred embodiment, at least one of the heat pipes of each heat pipe group further has a bent portion, and the bent portion is located between the evaporation section and the condensation section.

In a preferred embodiment, the heat-generating elements include at least one first heat-generating element and at least one second heat-generating element. The at least one first heat-generating element is mounted on the first surface, and the at least one second heat-generating element is mounted on the second surface. Furthermore, the first heat-generating element is a high-frequency power device, the second heat-generating element is a low-frequency power device, and a high-frequency circuit and a low-frequency circuit of the first heat-generating element and the second heat-generating element are isolated by the heat-dissipating substrate.

In a preferred embodiment, the heat-generating elements include an IGBT (Insulated Gate Bipolar Transistor), an IGCT (Integrated Gate Commutated Thyristor), an IEGT (Injection Enhanced Gate Transistor) or a diode.

The heat pipe groups corresponding to the heat-generating element are arranged at the same interval in parallel on the inner layer of the heat-dissipating substrate. Alternatively, the heat pipe groups corresponding to the heat-generating element are arranged in a staggered manner on the inner layer of the heat-dissipating substrate. More preferably, at least one heat pipe group includes a first heat pipe subgroup and a second heat pipe subgroup. The first heat pipe subgroup are fixed on the inner layer of the heat-dissipating substrate at a position near the first surface and the first heat-generating element; and the second heat pipe subgroup are fixed on the inner layer of the heat-dissipating substrate at a position near the second surface and the second heat-generating element.

The condensation sections of different groups of heat pipes are set to have the same length or different lengths according to a heating amount and heat dissipation requirement of the corresponding heat-generating element. The evaporation sections of the heat pipes buried in the inner layer of the heat-dissipating substrate are set to have the same depth or different depths according to installation position requirements of the corresponding heat-generating elements. The evaporation sections of different heat pipe groups are set to have the same heat pipe diameter or different heat pipe diameters according to heat dissipation requirements of the corresponding heat-generating elements. The number of the heat pipes corresponding to the different heat-generating elements is set according to respective heat dissipation requirements.

In a preferred embodiment, the heat pipes are gravity heat pipes, screen heat pipes, sintered heat pipes or groove heat pipes. Working liquid in the heat pipe is water, acetone, liquid ammonia, ethanol or R134a refrigerant.

In the application of the heat dissipation apparatus of the present invention, the heat-generating elements such as the power devices of the drive are placed on at least one surface of the heat-dissipating substrate; the heat pipe groups are buried in the inner layer of the heat-dissipating substrate; and the contact portions between the heat pipes and the fins are in triangle staggered arrangements, which can effectively improve the heat dissipation efficiency of each power device. In addition, the heat dissipation apparatus implements a compact arrangement of the power devices on the heat-dissipating substrate, and particularly reduces the electrical connection distance and reduces the leakage inductance on the transmission path for the parallel IGBT power devices. Furthermore, when the high-frequency IGBT and the low-frequency rectification bridge in the power devices and the bypass circuit are respectively placed on two sides of the substrate, the high-frequency circuit and the low-frequency circuit may be isolated, which reduces the interference of the high-frequency signal to the low-frequency signal and enhances the operation reliability of the drive.

### BRIEF DESCRIPTION OF THE DRAWINGS

The invention can be more fully understood by reading the following detailed description of the embodiment, with reference made to the accompanying drawings as follows:

FIG. 1 is a front view of a heat dissipation apparatus for a medium-voltage drive according to a preferred embodiment of the present invention;

FIG. 2 is a side view of a heat dissipation apparatus for a medium-voltage drive according to another preferred embodiment of the present invention;

FIG. 3 is a schematic view illustrating an arrangement of the contact areas between the plural groups of heat pipes and the fins of the heat dissipation apparatus in FIG. 1 or FIG. 2;

FIG. 4 is a back view of the heat dissipation apparatus in FIG. 2;

FIG. 5 illustrates heat pipes placed on a heat-dissipating substrate of the heat dissipation apparatus in FIG. 2 according to a preferred embodiment; and

FIG. 6 illustrates the heat pipes placed on the heat-dissipating substrate of the heat dissipation apparatus in FIG. 2 according to another preferred embodiment.

### DETAILED DESCRIPTION

Hereinafter, specific embodiments of the present invention are sufficiently explained with reference to the drawings.

In order to make the description of the present invention more detailed and more comprehensive, various embodiments are described below with reference to the accompanying drawings, wherein like reference numerals refer to like elements throughout. However, these embodiments are not intended to limit the present invention. The description of structure operation does not mean to limit its implementation order. Any device with equivalent functions that is produced from a structure formed by recombination of elements shall fall within the scope of the present invention.

The drawings are only illustrative and are not made according to the original size. In addition, well-known elements and steps are not described in the embodiments to avoid causing unnecessary limitations to the present invention.

FIG. 1 is a front view of a heat dissipation apparatus for a medium-voltage drive according to a preferred embodiment of the present invention. Referring to FIG. 1, the heat dissipation apparatus, suitable for dissipating heat from a plurality of heat-generating elements in the medium-voltage drive, includes a heat-dissipating substrate 1, at least one heat pipe group 2 and a plurality of fins 3. The contact portions between the at least one heat pipe group 2 and the fins 3 are in staggered arrangements.

The heat-dissipating substrate 1 has a first surface (or referred to as a front side), a second surface (or referred to as a back side) and an inner layer between the first surface and the second surface. The heat-generating elements are placed on at least one of the first surface and the second surface. The heat-generating elements include an IGBT (Insulated Gate Bipolar Transistor), an IGCT (Integrated Gate Commutated Thyristor), an IEGT (Injection Enhanced Gate Transistor) or a diode. For example, the heat-generating elements are placed on the first surface. In another example, the heat-generating elements are placed on the second surface. In a further example, the heat-generating elements are placed on both of the first surface and the second surface.

Each heat pipe group 2 includes a plurality of heat pipes. Each heat pipe has an evaporation section and a condensation section, and the evaporation section is buried in the inner layer of the heat-dissipating substrate 1 for absorbing the heat from the heat-generating elements. For example, the heat-generating element 4 (e.g. a power device) in FIG. 1 are corresponding to two heat pipes, and the heat from the heat-generating element 4 is dissipated by the two heat pipes. The fins 3 are arranged to be intersected with each heat pipe. For example, the fins are intersected with each heat pipe with an intersection angle of 90°. The fins 3 are fixed and connected to the condensation sections 22 of the heat pipes, so as to transfer the heat released by the condensation sections 22 to air. For example, the heat pipes 2 are arranged in a vertical direction and the fins 3 are parallel to one another and are arranged in a horizontal direction. To make the temperature of the fins more uniform and improve the heat dissipation efficiency of the fins, the contact portions between the plural groups of heat pipes and the fins are in staggered arrangements.

In a specific embodiment, at least one heat pipe of each of the heat pipe groups 2 further has a bent portion between the evaporation section 21 and the condensation section 22, so that other electronic elements may be placed in the space generated by the bent portions. For example, each heat pipe of each heat pipe group includes a bent portion, that is, each heat pipe is formed by the evaporation section 21, the bent portion and the condensation section 22. As another example, some heat pipes of each heat pipe group include the bent portions, but the other heat pipes do not include the bent portions.

As previously mentioned, in the prior art, when the heat-generating elements are mounted on the substrate of the heat dissipation apparatus, the power devices have to be distributed at larger intervals on the substrate of the heat dissipation apparatus, so as to quickly dissipate the heat generated by the power devices to air. However, the larger interval between the power devices increases the electrical connection distance between the power devices, and results in the increase of leakage inductance. In comparison, in the heat dissipation apparatus of the present invention in FIG. 1, the heat-generating elements of the drive are placed on the front side or back side of the heat-dissipating substrate 1; and the heat pipe groups 2 are buried in the inner layer of the heat-dissipating substrate 1, so that the heat from the heat-generating elements may be dissipated uniformly, thereby effectively improving the heat dissipation efficiency of each heat-generating element.

In a specific embodiment, the heat pipe groups are gravity heat pipes arranged vertically. Specifically, the condensation sections 22 of the gravity heat pipes are placed above the evaporation sections 21. When the temperature of the power devices rises, the working liquid in the evaporation sections 21 absorbs the heat, and then the liquid evaporates and converts into vapor which moves upwardly inside the cavity of the heat pipes to reach the condensation sections 22. The condensation sections 22 release and then transfer the heat carried by the vapor to the fins, and the vapor after releasing the heat becomes to liquid once again. The condensed liquid flows back to the lower evaporation sections from the upper condensation sections of the heat pipes along an inner wall of the heat pipes under gravity and/or capillary force, and then the next evaporation/condensation loop starts. Furthermore, the heat pipes may be gravity heat pipes without capillary structures disposed on respective inner walls thereof, or screen heat pipes with metal screen capillary structures disposed therein, or groove heat pipes with groove capillary structures disposed on respective inner walls thereof, or sintered heat pipes with metal powder sintered capillary structures disposed on respective inner walls thereof. The capillary force provided by the capillary structures is supplemented for a pushing force of the gravity backflow, and meanwhile the capillary structures may enhance the evaporation heat absorption process and the condensation heat release process, thereby increasing the heat transfer rate of the heat pipes and improving the heat dissipation effect. To reduce the cost of the heat dissipation apparatus, the groove copper-water heat pipe with low cost may be adopted in this embodiment. Preferably, the working liquid in the heat pipe is water, acetone, liquid ammonia, ethanol or R134a refrigerant.

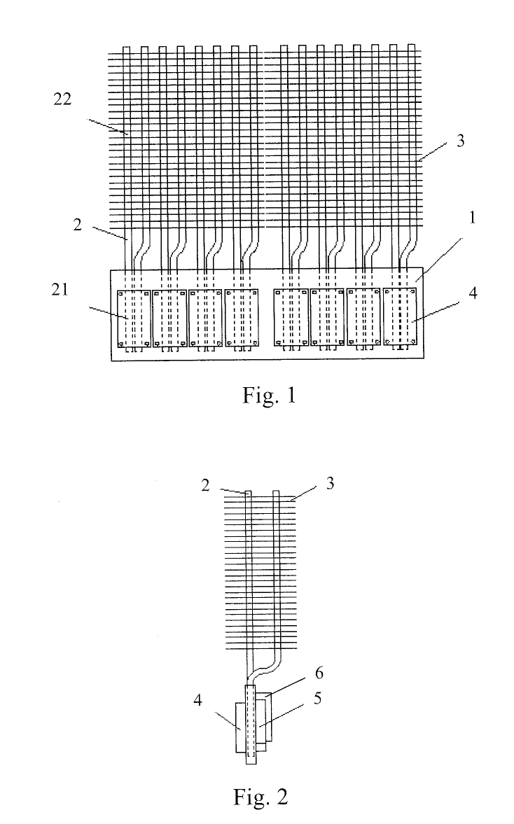

FIG. 2 is a side view of a heat dissipation apparatus for a medium-voltage drive according to another preferred embodiment of the present invention. FIG. 3 is a schematic view illustrating an arrangement of the contact areas between the heat pipe groups and the fins of the heat dissipation apparatus in FIG. 1 or FIG. 2. Referring to FIG. 2, the heat-generating elements may include a first heat-generating element 4 and heat-generating heating elements 5 and 6. The first heat-generating element is placed on the first surface, and the second heat-generating elements are placed on the second surface. Preferably, the first heat-generating element is a high-frequency power device; the second heat-generating elements are low-frequency power devices; and a high-frequency circuit and a low-frequency circuit of the first heat-generating element and the second heat-generating elements are isolated by the heat-dissipating substrate 1. It is known from the above that some heat-generating elements are placed on the front side of the heat-dissipating substrate and the other heat-generating elements are placed on the back side of the heat-dissipating substrate. When the evaporation sections of the heat pipe groups 2 are buried in the inner layer of the heat-dissipating substrate 1, the above-mentioned configuration allows the heat from the heat-generating elements to be dissipated uniformly, thereby effectively improving the heat dissipation efficiency of each heat-generating element. Moreover, the heat dissipation apparatus implements a compact arrangement of the heat-generating elements such as the power devices on the heat-dissipating substrate 1, and particularly reduces the electrical connection distance and reduces the leakage inductance on the transmission path for the parallel IGBT power devices. As shown in FIG. 3, the contact portions between the at least one heat pipe group 2 and the fins 3 are in staggered arrangements. When the condensation sections 22 of the heat pipes 2 receive the heat from the evaporation sections 21, the temperature of the fins connected to the condensation sections 22 is uniform and the heat dissipation efficiency is high.

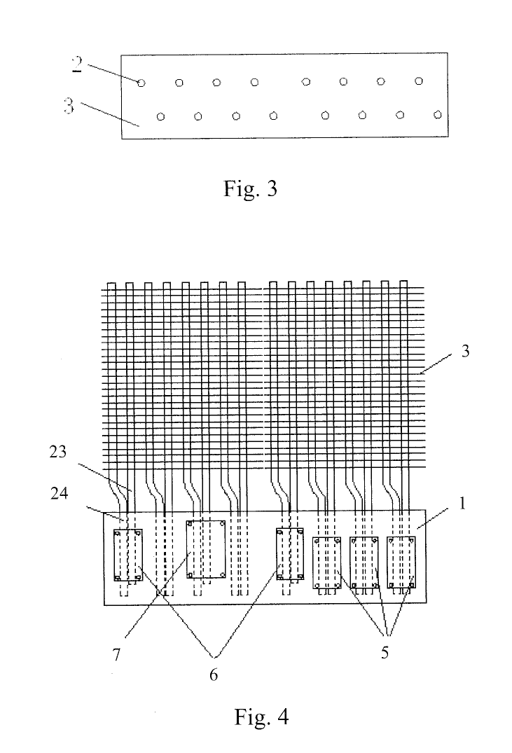

FIG. 4 is a back view of the heat dissipation apparatus in FIG. 2. Referring to FIG. 4, the evaporation section of each heat pipe of each heat pipe group is buried in the inner layer of the heat-dissipating substrate 1, as indicated by the dashed line in the figure. The power devices 5, 6 and 7 are installed on the back side of the heat-dissipating substrate 1. Preferably, the power device 5 is a diode on a rectification bridge, and the power device 6 is a diode on a bridge bypass unit, and the power device 7 is a thyristor on the bridge bypass unit, which are all low-frequency power devices.

Furthermore, the heat pipes corresponding to each power device include a straight pipe 23 and a bent pipe 24 with a bent portion, such that a space is reserved on the side of the rectifier unit and the bypass unit of heat-dissipating substrate 1 to install a control board, thereby implementing a compact arrangement of the power devices.

It should be understood by those skilled in the art that the heat generated by different power devices during normal operation is different. Thus, in order to reduce the material cost of the heat dissipation apparatus and take the heat dissipation efficiency of the power devices into account, the above-mentioned heat dissipation apparatus of the present invention may be altered, and the altered heat dissipation structures also fall within the spirit scope of the present invention.

In a specific embodiment, the condensation sections of different heat pipe groups are set to have the same length or different lengths according to heating amount and heat dissipation requirements of the corresponding heat-generating elements. For example, when the first heat-generating element and the second heat-generating element are both diodes, the heat dissipation requirement is relatively low, and thus the length of the condensation sections of the corresponding heat pipes may be reduced to avoid the waste of the heat pipe material. For example, when the first heat-generating element is an IGBT and the second heat-generating element is a thyristor, as the heat dissipation requirement of the IGBT is relatively high, the condensation sections of the corresponding heat pipes may be lengthened. At the same time, as the heat dissipation requirement of the thyristor is relatively low, the condensation sections of the corresponding heat pipes may be shortened.

In another specific embodiment, the evaporation section of each heat pipe buried in the inner layer of the heat-dissipating substrate is set to have the same depth or different depths according to an installation position requirement of the corresponding heat-generating element. Furthermore, the evaporation sections of different heat pipe groups are set to have the same heat pipe diameter or different heat pipe diameters according to a heat dissipation requirement of the corresponding heat-generating elements (for example, the heat dissipation requirement is associated with contact areas between the heat-generating elements and the heat-dissipating substrate, heating power, and the highest required substrate temperature). For example, when the first heat-generating element and the second heat-generating element are both diodes, the heat dissipation requirement is relatively low, such that the heat pipe with a small diameter may be selected, thereby avoiding the increase of the cost of heat pipes if the heat pipes with a larger diameter are adopted. For example, when the first heat-generating element is an IGBT and the second heat-generating element is a thyristor, as the heat dissipation requirement of the IGBT is relatively high, the heat pipes with a larger diameter may be adopted to meet the requirement for quick heat dissipation of the IGBT. At the same time, as the heat dissipation requirement of the thyristor is relatively low, the heat pipes with a small diameter may be adopted.

In still another specific embodiment, the number of the heat pipes corresponding to the different heat-generating elements is set according to the respective heat dissipation requirement. For example, when the first heat-generating element is an IGBT and the second heat-generating element is a thyristor, as the heat dissipation requirement of the IGBT is relatively high, more heat pipes may be disposed to dissipate the heat from the IGBT. At the same time, as the heat dissipation requirement of the thyristor is relatively low, less heat pipes may be disposed to dissipate the heat from the thyristor.

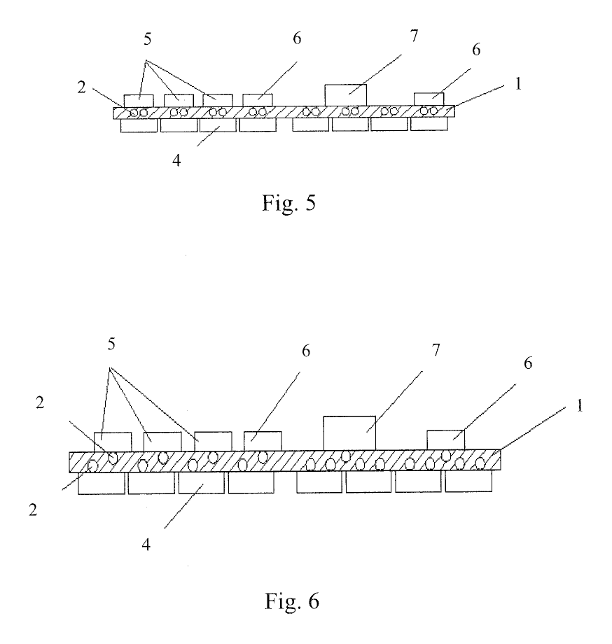

FIG. 5 illustrates heat pipes placed on a heat-dissipating substrate of the heat dissipation apparatus in FIG. 2 according to a preferred embodiment. Referring to FIG. 5, the heat-dissipating substrate 1 includes an upper surface and a lower surface. The power devices 5, 6 and 7 are disposed on the upper surface of the heat-dissipating substrate 1; and the power devices 4 are disposed on the lower surface of the heat-dissipating substrate 1. When the inner layer of the heat-dissipating substrate 1 is thin, each heat pipe group corresponding to the heat-generating elements are arranged at the same interval in parallel on the inner layer of the heat-dissipating substrate, so as to avoid penetrating the heat pipes when the power devices are installed. It should be understood by those skilled in the art that the preferred embodiment disclosed in FIG. 4 is also applicable to the arrangement of the heat pipes in FIG. 5. For example, the evaporation sections of different heat pipe groups are set to have the same heat pipe diameter or different heat pipe diameters according to the heating amount and heat dissipation requirement of the corresponding heat-generating element. As another example, the number of the heat pipes corresponding to the different heat-generating elements is set according to the respective heat dissipation requirement.

FIG. 6 illustrates the heat pipes placed on the heat-dissipating substrate of the heat dissipation apparatus in FIG. 2 according to another preferred embodiment. Similar to FIG. 5, the power devices 5, 6 and 7 are disposed on the upper surface of the heat-dissipating substrate 1; and the power devices 4 are disposed on the lower surface of the heat-dissipating substrate 1. When the inner layer of the heat-dissipating substrate is thick, each group of heat pipes corresponding to the heat-generating elements is arranged in a staggered manner on the inner layer of the heat-dissipating substrate. Preferably, the heat pipe groups include a first heat pipe subgroup and a second heat pipe subgroup. The first heat pipe subgroup are fixed on the inner layer of the heat-dissipating substrate at a position near the first surface and the first heat-generating elements (e.g. the power devices 5, 6 and 7); and the second heat pipe subgroup are fixed on the inner layer of the heat-dissipating substrate at a position near second surface and the second heat-generating element (e.g. the power devices 4). Similarly, the preferred embodiment disclosed in FIG. 4 is also applicable to the arrangement of the heat pipes in FIG. 6. For example, the evaporation sections of different heat pipe groups are set to have the same heat pipe diameter or different heat pipe diameters according to the heat dissipation requirement of the corresponding heat-generating element. As another example, the number of the heat pipes corresponding to the different heat-generating elements is set according to the respective heat dissipation requirement.

In the application of the heat dissipation apparatus of the present invention, the heat-generating elements such as the power devices of the drive are placed on at least one surface of the heat-dissipating substrate; the heat pipe groups are buried in the inner layer of the heat-dissipating substrate; and the contact portions between the heat pipes and the fins are in staggered arrangements, which can effectively improve the heat dissipation efficiency of each power device. In addition, the heat dissipation apparatus implements a compact arrangement of the power devices on the heat-dissipating substrate, and particularly reduces the electrical connection distance and reduces the leakage inductance on the transmission path for the parallel IGBT power devices. Furthermore, when the high-frequency IGBT and the low-frequency rectification bridge in the power devices and the bypass circuit are respectively placed on two sides of the substrate, the high-frequency circuit and the low-frequency circuit may be isolated, which reduces the interference of the high-frequency signal to the low-frequency signal and enhances the operation reliability of the drive.

Although the present invention has been disclosed with reference to the above embodiments, these embodiments are not intended to limit the present invention. It will be apparent to those skilled in the art that various modifications and variations can be made without departing from the scope or spirit of the present invention. Therefore, the scope of the present invention shall be defined by the appended claims.

What is claimed is:

1. A heat dissipation apparatus, suitable to dissipate heat from a plurality of heat-generating elements in a medium-voltage drive, comprising:
a heat-dissipating substrate having a first surface, a second surface and an inner layer between the first surface and the second surface, wherein the heat-generating elements are placed on at least one of the first surface and the second surface;
at least one heat pipe group, each of the at least one heat pipe group comprising a plurality of heat pipes, wherein each of the heat pipes has an evaporation section and a condensation section, and the evaporation section is buried in the inner layer of the heat-dissipating substrate for absorbing heat from the heat-generating elements; and
a plurality of fins arranged to be intersected with each of the heat pipes, and fixed and connected to the condensation section of each of the heat pipes, so as to transfer heat released by the condensation section to air,
wherein contact portions between the at least one heat pipe group and the fins are in staggered arrangements.

2. The heat dissipation apparatus of claim 1, wherein at least one of the heat pipes of each of the at least one heat pipe group further has a bent portion, and the bent portion is located between the evaporation section and the condensation section.

3. The heat dissipation apparatus of claim 1, wherein the heat-generating elements comprise at least one first heating element and at least one second heat-generating element, wherein the at least one first heat-generating element is placed on the first surface, and the at least one second heat-generating element is placed on the second surface.

4. The heat dissipation apparatus of claim 3, wherein the first heat-generating element is a high-frequency power device, and the second heat-generating element is a low-frequency power device, and a high-frequency circuit and a low-frequency circuit of the first heat-generating element and the second heat-generating element are isolated by the heat-dissipating substrate.

5. The heat dissipation apparatus of claim 1, wherein the heat-generating elements comprise an IGBT (Insulated Gate Bipolar Transistor), an IGCT (Integrated Gate Commutated Thyristor), an IEGT (Injection Enhanced Gate Transistor) or a diode.

6. The heat dissipation apparatus of claim 3, wherein the heat pipe groups corresponding to the heat-generating elements are arranged at the same interval in parallel on the inner layer of the heat-dissipating substrate.

7. The heat dissipation apparatus of claim 3, wherein the heat pipe groups corresponding to the heat-generating elements are arranged in a staggered manner on the inner layer of the heat-dissipating substrate.

8. The heat dissipation apparatus of claim 7, wherein the at least one heat pipe group comprises a first heat pipe subgroup and a second heat pipe subgroup; the first heat pipe subgroup is fixed on the inner layer of the heat-dissipating substrate at a position near the first surface and the first heat-generating element; and the second heat pipe subgroup is fixed on the inner layer of the heat-dissipating substrate at a position near the second surface and the second heat-generating element.

9. The heat dissipation apparatus of claim 1, wherein the condensation sections of different heat pipe groups are set to have the same length or different lengths according to heat generation and heat dissipation requirements of the heat-generating elements corresponding thereto.

10. The heat dissipation apparatus of claim 1, wherein the evaporation sections of the heat pipes buried in the inner layer of the heat-dissipating substrate are set to have the same depth or different depths according to installation position requirements of the heat-generating elements corresponding thereto.

11. The heat dissipation apparatus of claim 1, wherein the evaporation sections of different heat pipe groups are set to have the same heat pipe diameter or different heat pipe diameters according to heat dissipation requirements of the heat-generating elements corresponding thereto.

12. The heat dissipation apparatus of claim 1, wherein the number of the heat pipes corresponding to different heat-generating elements is set according to respective heat dissipation requirements.

13. The heat dissipation apparatus of claim 1, wherein the heat pipes are gravity heat pipes, screen heat pipes, sintered heat pipes or groove heat pipes.

14. The heat dissipation apparatus of claim 13, wherein working liquid in the heat pipes is water, acetone, liquid ammonia, ethanol or R134a refrigerant.

15. The heat dissipation apparatus of claim 1, wherein the fins are intersected with each of the heat pipes with an intersection angle of 90°.
